(19) United States
(12) Patent Application Publication
(10) Pub. No.: US 2022/0051962 A1
(43) Pub. Date: Feb. 17, 2022

(54) SEMICONDUCTOR DEVICE ASSEMBLIES AND SYSTEMS WITH INTERNAL THERMAL BARRIERS AND METHODS FOR MAKING THE SAME

(71) Applicant: Micron Technology, Inc., Boise, ID (US)

(72) Inventors: Owen R. Fay, Meridian, ID (US); Madison E. Wale, Boise, ID (US); James L. Voelz, Boise, ID (US); Dylan W. Southern, Meridian, ID (US)

(21) Appl. No.: 16/991,982

(22) Filed: Aug. 12, 2020

(51) Int. Cl. H01L 23/367; H01L 23/373; H01L 23/31; H01L 21/48

(52) U.S. Cl. CPC H01L 23/3672; H01L 21/4882; H01L 23/3164; H01L 23/3735

(57) ABSTRACT

Semiconductor device assemblies are provided with a layer of thermal barrier material between a first semiconductor device (e.g., a logic die or other heat-generating device) and a second semiconductor device (e.g., a memory die or other device whose performance may be improved in a lower-temperature environment). The layer of thermal barrier material can reduce the conduction of the heat generated by the first semiconductor device towards the second semiconductor device. The assemblies can also include one or more thermally conductive structures disposed in the substrate under the first semiconductor device and configured to conduct the heat from the first semiconductor device out of the semiconductor device assembly.

### TECHNICAL FIELD

The present disclosure generally relates to semiconductor devices, and more particularly relates to semiconductor device assemblies and systems with internal thermal barriers and methods for making the same.

### BACKGROUND

Packaged semiconductor dies, including memory chips, microprocessor chips, and imager chips, typically include one or more semiconductor dies mounted on a substrate and encased in a protective covering or capped with a heat-conducting lid. In operation, semiconductor dies can generate heat, which can pose a challenge for package design as the number of devices and the power density thereof increases. Various approaches to managing the generated heat include providing heat dissipating structures such as lids or heat sinks over the semiconductor dies to assist with heat exchange between the package and the environment in which it operates. Additional approaches to better manage heat generated by packaged semiconductor dies are desired.

### BRIEF DESCRIPTION OF THE DRAWINGS

FIG. 1 is a simplified schematic cross-sectional view of a semiconductor device assembly.

FIG. 2 is a simplified schematic cross-sectional view of a semiconductor device assembly in accordance with an embodiment of the present technology.

FIG. 3 is a simplified schematic cross-sectional view of a semiconductor device assembly in accordance with an embodiment of the present technology.

FIG. 4 is a simplified schematic cross-sectional view of a semiconductor device assembly in accordance with an embodiment of the present technology.

FIG. 5 is a simplified schematic cross-sectional view of a semiconductor device assembly in accordance with an embodiment of the present technology.

FIG. 6 is a simplified schematic cross-sectional view of a semiconductor device assembly in accordance with an embodiment of the present technology.

FIG. 7 is a simplified schematic cross-sectional view of a semiconductor device assembly in accordance with an embodiment of the present technology.

FIG. 8 is a schematic view showing a system that includes a semiconductor device assembly configured in accordance with an embodiment of the present technology.

FIG. 9 is a flow chart illustrating a method of making a semiconductor device assembly in accordance with an embodiment of the present technology.

### DETAILED DESCRIPTION

Specific details of several embodiments of semiconductor devices, and associated systems and methods, are described below. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, chemical-mechanical planarization, or other suitable techniques.

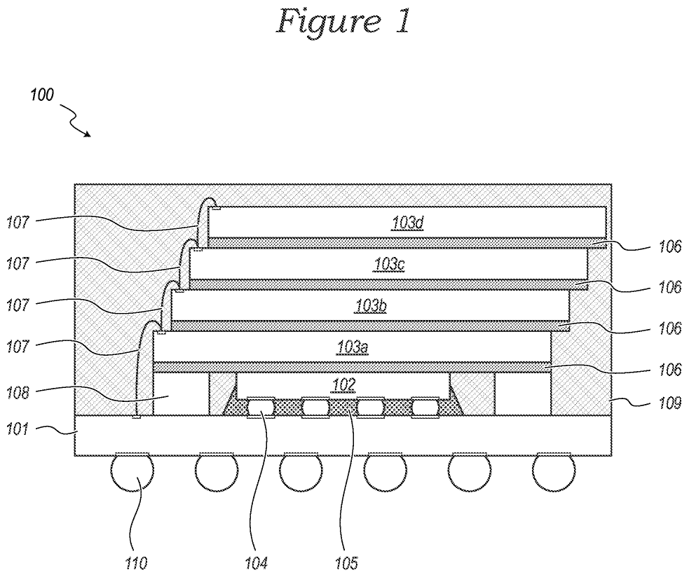

FIG. 1 is a simplified schematic cross-sectional view of an exemplary semiconductor device assembly 100. The assembly 100 includes a package substrate 101 over which are disposed a plurality of semiconductor dies. In the particular arrangement illustrated in FIG. 1, the assembly 100 includes a first semiconductor die 102 of a first type (e.g., a logic die) and a stack of four second semiconductor dies 103a-103d of a second type (e.g., memory dies). The first semiconductor die 102 can be electrically connected to the package substrate 101 by a plurality of interconnects 104 (e.g., one or more solder balls, copper pillars, copper pads, etc.) and an underfill material 105. Each of the four second semiconductor dies 103a-103d can be connected to a lower structure (e.g., the first semiconductor die 102 and/or one or more spacers 108 for the lowest second semiconductor die 103a, and a lower one of the second semiconductor dies 103a-103c for the remaining semiconductor dies 103b-103d) by a die attach film (DAF) or a wafer-level non-conductive film (NCF) 106 (e.g., optionally comprising any one of a variety of non-conductive polymers and/or b-staged epoxies) and electrically connected to the substrate 101 and/or one another by a plurality of wirebonds 107. The dies and the package substrate can be at least partially encapsulated by an encapsulant material 109 (e.g., mold resin or the like). When integrated into a larger system, the assembly 100 may be connected by a plurality of package interconnects 110 (e.g., solder balls) to another device (e.g., system-level board).

In the assembly 100 of FIG. 1, the first semiconductor die 102 may generate significantly more heat during operation than the second semiconductor dies 103a-103d, due to the more power-intensive function fulfilled by a logic die. Although the second semiconductor die 102 may be capable of operating correctly at a high temperature that results from this generated heat, the second semiconductor dies 103a-103d, through which some of the heat generated by the first semiconductor die 102 flows, may not be capable of operating correctly at similarly high temperatures. Accordingly, to avoid unreliable operation, the first semiconductor die 102 may need to be operated more slowly to keep the second semiconductor dies 103a-103d operating within a specified temperature range.

To address this limitation, in the embodiments described below, semiconductor device assemblies can include a layer of thermal barrier material between a first semiconductor device (e.g., a logic die or other heat-generating device) and a second semiconductor device (e.g., a memory die or other device whose performance may be improved in a lower-temperature environment). The layer of thermal barrier material can reduce the conduction of the heat generated by the first semiconductor device towards the second semiconductor device.

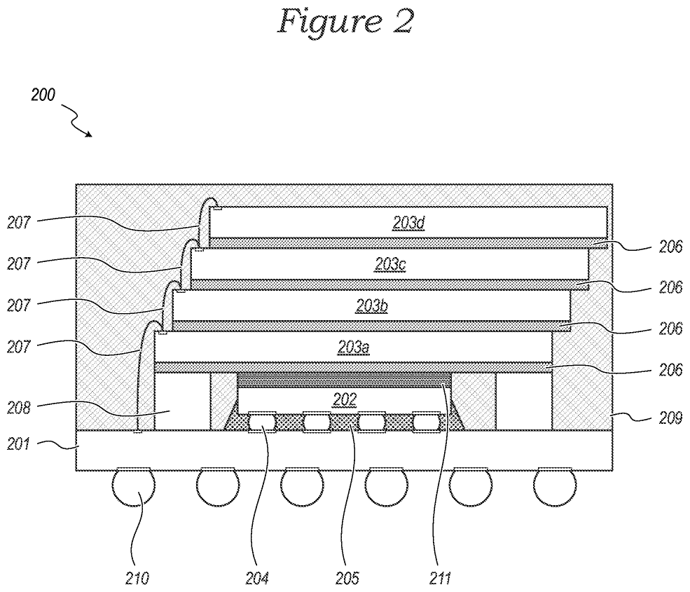

FIG. 2 is a simplified schematic cross-sectional view of a semiconductor device assembly in accordance with an embodiment of the present technology. The assembly 200 includes a package substrate 201 over which are disposed a plurality of semiconductor dies. In the particular arrangement illustrated in FIG. 2, the assembly 200 includes a first semiconductor die 202 of a first type (e.g., a logic die) and a stack of four second semiconductor dies 203a-203d of a second type (e.g., memory dies). The first semiconductor die 202 can be electrically connected to the package substrate 201 by a plurality of interconnects 204 (e.g., one or more solder balls, copper pillars, copper pads, etc.) and an underfill material 205. Each of the four second semiconductor dies 203a-203d can be connected to a lower structure (e.g., the first semiconductor die 202 and/or one or more spacers 208 for the lowest second semiconductor die 203a, and a lower one of the second semiconductor dies 203a-203c for the remaining semiconductor dies 203b-203d) by a DAF or NCF 206 and electrically connected to the substrate 201 and/or one another by a plurality of wirebonds 207. The dies and the package substrate can be at least partially encapsulated by an encapsulant material 209 (e.g., mold resin or the like). When integrated into a larger system, the assembly 200 may be connected by a plurality of package interconnects 210 (e.g., solder balls) to another device (e.g., system-level board).

To improve the thermal performance of the assembly 200, a layer of thermal barrier material 211 is disposed between the first semiconductor die 202 and a lowermost one of the second semiconductor dies 203a. The thermal barrier material of the layer 211 can have a low thermal conductivity κ (i.e., a high thermal resistivity RA). For example, the thermal barrier material of the layer 211 can have a thermal conductivity K of less than 5 W/(m ° K), less than 2 W/(m ° K), less than 1 W/(m ° K), or less than 0.5 W/(m ° K) in the z-direction (e.g., in the direction along which the first and second semiconductor die are spaced) to reduce or prevent the conduction of heat generated by the first semiconductor die 202 towards the second semiconductor dies 203a-203d. In this regard, the layer of thermal barrier material 211 can be configured to provide a rate of heat transfer towards the package substrate 201 that is greater than a rate of heat transfer towards the second semiconductor dies 203a-203d. According to one aspect of the present disclosure, during operation of the assembly 200, a temperature gradient across the layer of thermal barrier material 211 may be greater than a temperature gradient from a portion (e.g., an upper surface, a lower surface, an intermediate point) of the first semiconductor die 202 and a portion (e.g., an upper surface, a lower surface, an intermediate point) of the package substrate 201. In accordance with one aspect of the present disclosure, the thermal barrier material of the layer 211 can be a different material than the encapsulant material 209 and can have a thermal conductivity less than that of the encapsulant material 209. The layer of thermal barrier material 211 can comprise one or more of a number of materials with the requisite thermal conductivity, including a silicon oxide glass (κ=0.5-1.2 W/(m ° K)), thick tetraethoxysilane (TEOS) (κ=0.1 W/(m ° K)), polyimide (κ=0.2-2.0 W/(m ° K)), ceramic (e.g., AlOₓ) or the like.

In accordance with one aspect of the present disclosure, the layer of thermal barrier material 211 can have a thickness of between about 2 μm and 50 μm. Accordingly, the contribution of the layer of thermal barrier material 211 to the overall package height of the semiconductor device assembly 200 can be minimal. In other embodiments, the thickness of the layer of thermal barrier material can be greater or lesser than this range, depending upon the desired overall package height, the properties of the thermal barrier material used, and the amount of heat generated by the first semiconductor die. For example, in some embodiments in which silicon oxide glass is used as the thermal barrier material, the layer of thermal barrier material 211 can have a thickness of less than 10 μm and still provide a significant thermal barrier in the z-direction. In other embodiments in which a material with an even lower thermal conductivity κ is used, such as polyimide, the thickness of the layer of thermal barrier material 211 can be even less (e.g., less than 5 μm). In accordance with one aspect of the present disclosure, the thickness of a layer of thermal barrier material may correspond to its thermal conductivity (e.g., thinner layers of a material with lower thermal conductivity may be capable of substantially the same reductions in heat conduction in the z-direction as thicker layers of a material with higher thermal conductivity).

In one embodiment, the layer of thermal barrier material 211 can be provided on the backside of the first semiconductor die 202 while multiple such dies are still in wafer form (e.g., in back-end processing). The layer of thermal barrier material 211 can be provided by any one of a number of deposition processes readily known to those skilled in the art, including sputtering, chemical vapor deposition (CVD), physical vapor deposition (PVD), atomic layer deposition (ALD), liquid application followed by curing, spin coating, tape application, attachment with adhesives, etc. Because back-side processing is usually completed after the front-side fabrication of the active layer of a die (e.g., formation of the semiconductor device structures therein), in some embodiments the deposition process can be constrained to a temperature sufficiently low to avoid causing heat-induced damage to the semiconductor device structures in the dies (e.g., at temperatures below about 300° C., or below about 250° C., or even below about 200° C.).

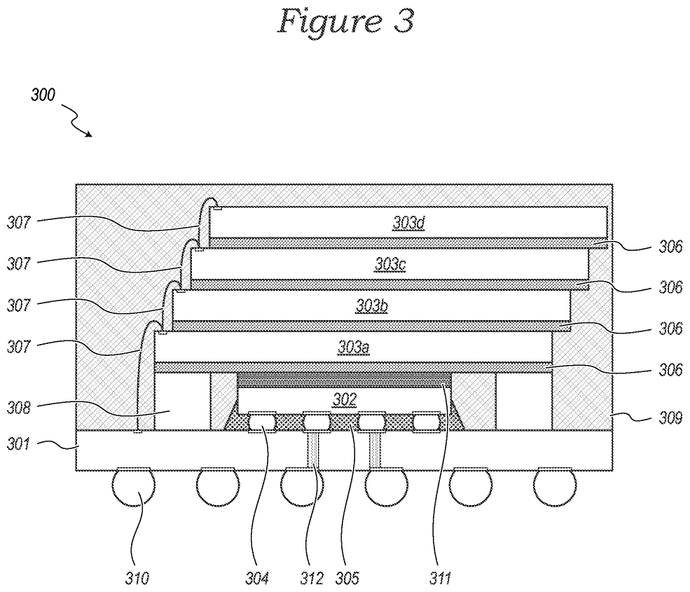

In accordance with one aspect of the present disclosure, providing a layer of thermal barrier material 211 over the first semiconductor die 202 can reduce the conduction of heat generated by the first semiconductor die 202 in an undesirable direction (e.g., towards the stack of second semiconductor dies 203a-203d). The heat generated by the first semiconductor die 211 will therefore preferentially conduct in other more desirable directions (e.g., laterally through the package towards the vertical side edges thereof, downwards through the substrate of the package). To further improve the conduction of heat generated by the first semiconductor die 202 in a preferred direction, in some embodiments of the present disclosure heat conducting structures may also be provided. FIG. 3 illustrates one such embodiment, in which heat conducting structures are provided to conduct heat downwardly through the substrate.

FIG. 3 is a simplified schematic cross-sectional view of a semiconductor device assembly in accordance with an embodiment of the present technology. The assembly 300 includes a package substrate 301 over which are disposed a plurality of semiconductor dies. In the particular arrangement illustrated in FIG. 3, the assembly 300 includes a first semiconductor die 302 of a first type (e.g., a logic die) and a stack of four second semiconductor dies 303a-303d of a second type (e.g., memory dies). The first semiconductor die 302 can be electrically connected to the package substrate 301 by a plurality of interconnects 304 (e.g., one or more solder balls, copper pillars, copper pads, etc.) and an underfill material 305. Each of the four second semiconductor dies 303a-303d can be connected to a lower structure (e.g., the first semiconductor die 302 and/or one or more spacers 308 for the lowest second semiconductor die 303a, and a lower one of the second semiconductor dies 303a-303c for the remaining semiconductor dies 303b-303d) by a DAF or NCF 306 and electrically connected to the substrate 301 and/or one another by a plurality of wirebonds 307. The dies and the package substrate can be at least partially encapsulated by an encapsulant material 309 (e.g., mold resin or the like). When integrated into a larger system, the assembly 300 may be connected by a plurality of package interconnects 310 (e.g., solder balls) to another device (e.g., system-level board).

To improve the thermal performance of the assembly 300, a layer of thermal barrier material 311 is disposed between the first semiconductor die 302 and a lowermost one of the second semiconductor dies 303a, as set forth in greater detail above with respect to FIG. 2. To further improve thermal performance of the assembly, thermal conducting structures 312 (e.g., vias, heat pipes, metal plugs, etc.) are also provided in substrate 301, to conduct heat generated by the first semiconductor die 202 downwardly through the substrate 301. The material of thermal conducting structures 312 can have a high thermal conductivity κ, such as copper (κ=400 W/(m ° K)), aluminum (κ=237 W/(m ° K)), alloys thereof, or the like. The thermal conducting structures 312 may extend from an upper surface of the substrate 301 to a lower surface thereof, and may optionally be connected to thermally conductive interconnects (e.g., solder balls 304, 310) that are electrically isolated from the circuits of the first semiconductor device (e.g., “dummy” bumps). Alternatively, the interconnects to which the thermal conducting structures 312 are connected may serve double-duty as “live” interconnects (e.g., providing power, grounding, or signals to the first semiconductor device). By connecting thermal conducting structures 312 to a package interconnect 310 on the lower surface of the substrate 301, a thermal circuit can be formed with the system-level board to which the assembly 300 is connected, and which can be provided with heat dissipation structures (e.g., heat sinks, heat fins, etc.) to further improve the thermal management of assembly 300.

In accordance with one aspect of the present disclosure, the inclusion of both a layer of thermal barrier material disposed over a die and one or more thermal conducting structures disposed in the substrate under a die can preferentially conduct the majority of the heat generated by a die in a desired direction (e.g., through the thermal conducting structures and out of the assembly). In this regard, depending upon the size, thickness, and composition of the layer of thermal barrier material and the size, number, and composition of the thermal conducting structures, the majority (e.g., more than 50%, more than 66%, more than 75%, or even more than 90%) of the heat generated by the die can be conducted away from other dies in the assembly.

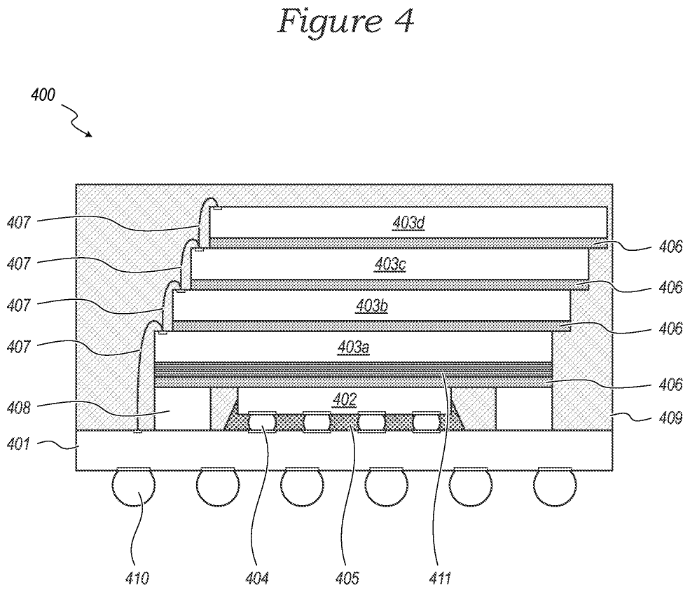

Although in the foregoing example embodiment semiconductor device assemblies have been illustrated and described in which layers of thermal barrier are illustrated as approximately coextensive in size with the die whose generated heat they are configured to manage, in other embodiments layers of thermal barrier material having different sizes may also be used. For example, FIG. 4 is a simplified schematic cross-sectional view of a semiconductor device assembly in accordance with an embodiment of the present technology. The assembly 400 includes a package substrate 401 over which are disposed a plurality of semiconductor dies. In the particular arrangement illustrated in FIG. 4, the assembly 400 includes a first semiconductor die 402 of a first type (e.g., a logic die) and a stack of four second semiconductor dies 403a-403d of a second type (e.g., memory dies). The first semiconductor die 402 can be electrically connected to the package substrate 401 by a plurality of interconnects 404 (e.g., one or more solder balls, copper pillars, copper pads, etc.) and an underfill material 405. Each of the four second semiconductor dies 403a-403d can be connected to a lower structure (e.g., the first semiconductor die 402 and/or one or more spacers 408 for the lowest second semiconductor die 403a, and a lower one of the second semiconductor dies 403a-403c for the remaining semiconductor dies 403b-403d) by a DAF or NCF 406 and electrically connected to the substrate 401 and/or one another by a plurality of wirebonds 407. The dies and the package substrate can be at least partially encapsulated by an encapsulant material 409 (e.g., mold resin or the like). When integrated into a larger system, the assembly 400 may be connected by a plurality of package interconnects 410 (e.g., solder balls) to another device (e.g., system-level board).

To improve the thermal performance of the assembly 400, a layer of thermal barrier material 411 is disposed between the first semiconductor die 402 and a lowermost one of the second semiconductor dies 403a. Unlike the layer of thermal barrier material 311 illustrated in FIG. 3, the layer of thermal barrier material 411 in the assembly 400 of FIG. 4 extends beyond the top surface of the second semiconductor die 402. In the particular example of FIG. 4, the layer of thermal barrier material 411 has a size approximately the same as (e.g., within 1% of, within 5% of, or within 10% of) the size of the second semiconductor die 403a closest to the first semiconductor die 402. This arrangement can be provided by including the layer of thermal barrier material 411 on the back surface of the second semiconductor die 403a, rather than on the back surface of the first semiconductor die 402. In this regard, as can be seen with reference to FIG. 4, the layer of die attach film 406 adhering the lowest second semiconductor die 403a to the first semiconductor die 402 and to the spacers 408 is formed over the layer of thermal barrier material 411.

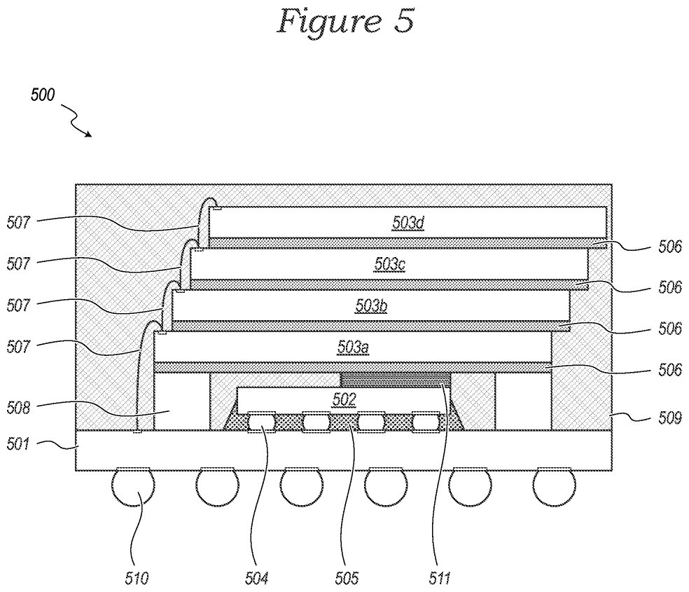

In yet another embodiment, a layer of thermal barrier material may be provided just over that portion of those portions of a semiconductor die where a high density of power consuming circuits are located, rather than over the whole surface of a die. FIG. 5 illustrates one such example assembly 500 in accordance with an embodiment of the present disclosure. As can be seen with reference to FIG. 5, assembly 500 includes a package substrate 501 over which are disposed a plurality of semiconductor dies. In the particular arrangement illustrated in FIG. 5, the assembly 500 includes a first semiconductor die 502 of a first type (e.g., a logic die) and a stack of four second semiconductor dies 503a-503d of a second type (e.g., memory dies). The first semiconductor die 502 can be electrically connected to the package substrate 501 by a plurality of interconnects 504 (e.g., one or more solder balls, copper pillars, copper pads, etc.) and an underfill material 505. Each of the four second semiconductor dies 503a-503d can be connected to a lower structure (e.g., the first semiconductor die 502 and/or one or more spacers 508 for the lowest second semiconductor die 503a, and a lower one of the second semiconductor dies 503a-503c for the remaining semiconductor dies 503b-503d) by a DAF or NCF 506 and electrically connected to the substrate 501 and/or one another by a plurality of wirebonds 507. The dies and the package substrate can be at least partially encapsulated by an encapsulant material 509 (e.g., mold resin or the like). When integrated into a larger system, the assembly 500 may be connected by a plurality of package interconnects 510 (e.g., solder balls) to another device (e.g., system-level board).

To improve the thermal performance of the assembly 500, a layer of thermal barrier material 511 is over a portion of the first semiconductor die 502. Unlike the layer of thermal barrier material 311 illustrated in FIG. 3, the layer of thermal barrier material 511 in the assembly 500 of FIG. 5 extends only partway over the top surface of the second semiconductor die 502. In the particular example of FIG. 5, the layer of thermal barrier material 511 has a size significantly less than (e.g., less than 75% of, less than 50% of, or less than 33% of) the size of the first semiconductor die 502. Such an arrangement may be beneficial when a particular region of first semiconductor die 502 is prone to generate large amounts of heat (e.g., due to the presence of a voltage drop circuit or the like).

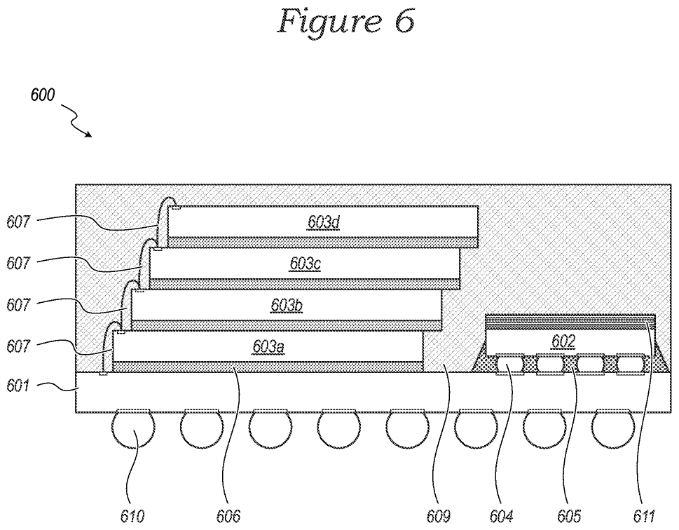

Although the foregoing example embodiments have been illustrated and described with reference to package assemblies including a stack of memory dies provided over a logic die, in other embodiments package assemblies with other arrangements can likewise benefit from the aforementioned techniques for improved thermal performance. For example, FIG. 6 is a simplified schematic cross-sectional view of a semiconductor device assembly in accordance with an embodiment of the present technology. The assembly 600 includes a package substrate 601 over which are disposed a plurality of semiconductor dies. In the particular arrangement illustrated in FIG. 6, the assembly 600 includes a first semiconductor die 602 of a first type (e.g., a logic die) and a stack of four second semiconductor dies 603a-603d of a second type (e.g., memory dies) disposed laterally away from the first semiconductor die 602. The first semiconductor die 602 can be electrically connected to the package substrate 601 by a plurality of interconnects 604 (e.g., one or more solder balls, copper pillars, copper pads, etc.) and an underfill material 605. Each of the four second semiconductor dies 603a-603d can be connected to a lower structure (e.g., the substrate 601 for the lowest second semiconductor die 603a, and a lower one of the second semiconductor dies 603a-603c for the remaining semiconductor dies 603b-603d) by a DAF or NCF 606 and electrically connected to the substrate 601 and/or one another by a plurality of wirebonds 607. The dies and the package substrate can be at least partially encapsulated by an encapsulant material 609 (e.g., mold resin or the like). When integrated into a larger system, the assembly 600 may be connected by a plurality of package interconnects 610 (e.g., solder balls) to another device (e.g., system-level board).

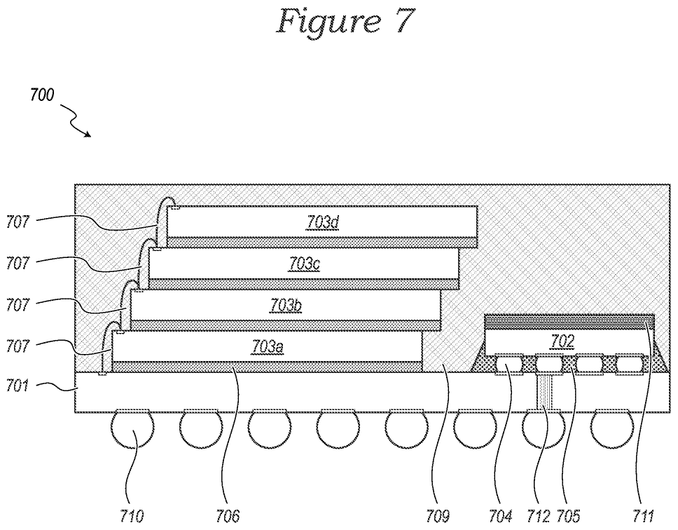

To improve the thermal performance of the assembly 600, a layer of thermal barrier material 611 is disposed over the first semiconductor die 602. In one embodiment, the layer of thermal barrier material 611 can be provided on the backside of the first semiconductor die 602 while multiple such dies are still in wafer form (e.g., in back-end processing). In accordance with one aspect of the present disclosure, providing a layer of thermal barrier material 611 over the first semiconductor die 602 can reduce the conduction of heat generated by the first semiconductor die 602 in an undesirable direction (e.g., into the encapsulant material 609). The heat generated by the first semiconductor die 611 will therefore preferentially conduct in other more desirable directions (e.g., downwards through the substrate of the package). To further improve the conduction of heat generated by the first semiconductor die 602 in a preferred direction, in some embodiments of the present disclosure heat conducting structures may also be provided. FIG. 7 illustrates one such embodiment, in which heat conducting structures are provided to conduct heat downwardly through the substrate.

FIG. 7 is a simplified schematic cross-sectional view of a semiconductor device assembly in accordance with an embodiment of the present technology. The assembly 700 includes a package substrate 701 over which are disposed a plurality of semiconductor dies. In the particular arrangement illustrated in FIG. 7, the assembly 700 includes a first semiconductor die 702 of a first type (e.g., a logic die) and a stack of four second semiconductor dies 703a-703d of a second type (e.g., memory dies) disposed laterally away from the first semiconductor die 702. The first semiconductor die 702 can be electrically connected to the package substrate 701 by a plurality of interconnects 704 (e.g., one or more solder balls, copper pillars, copper pads, etc.) and an underfill material 705. Each of the four second semiconductor dies 703a-703d can be connected to a lower structure (e.g., the substrate 701 for the lowest second semiconductor die 703a, and a lower one of the second semiconductor dies 703a-703c for the remaining semiconductor dies 703b-703d) by a DAF or NCF 706 and electrically connected to the substrate 701 and/or one another by a plurality of wirebonds 707. The dies and the package substrate can be at least partially encapsulated by an encapsulant material 709 (e.g., mold resin or the like). When integrated into a larger system, the assembly 700 may be connected by a plurality of package interconnects 710 (e.g., solder balls) to another device (e.g., system-level board).

To improve the thermal performance of the assembly 700, a layer of thermal barrier material 711 is disposed over the first semiconductor die 702. To further improve thermal performance of the assembly, thermal conducting structures 712 (e.g., vias, heat pipes, metal plugs, etc.) are also provided in substrate 701, to conduct heat generated by the first semiconductor die 202 downwardly through the substrate 701. The thermal conducting structures 712 may extend from an upper surface of the substrate 701 to a lower surface thereof, and may optionally be connected to thermally conductive interconnects (e.g., solder balls 704, 710) that are electrically isolated from the circuits of the first semiconductor device (e.g., “dummy” bumps). Alternatively, the interconnects to which the thermal conducting structures 712 are connected may serve double-duty as “live” interconnects (e.g., providing power, grounding, or signals to the first semiconductor device). By connecting thermal conducting structures 712 to a package interconnect 710 on the lower surface of the substrate 701, a thermal circuit can be formed with the system-level board to which the assembly 700 is connected, and which can be provided with heat dissipation structures (e.g., heat sinks, heat fins, etc.) to further improve the thermal management of assembly 700.

Although the foregoing example embodiments have been illustrated and described with a single layer of thermal barrier material on a die, in other embodiments a die could be provided with multiple layers of thermal barrier material to further reduce the conduction of heat generated in an assembly in an undesirable direction. For example, in one embodiment, a die could be provided with a stack of layers of thermal barrier material on a back side thereof. The layers could each comprise the same material, or could include different materials (e.g., depending upon the various design constraints of total package height, processing temperature limitations, etc.).

In accordance with one aspect of the present disclosure, although the foregoing example embodiments have been illustrated and described with reference to semiconductor device assemblies including multiple semiconductor dies and a substrate, in still other embodiments semiconductor device assemblies can include different arrangements. For example, package assemblies with different numbers and arrangements of dies can likewise benefit from the thermal management techniques described above. In this regard, a single device package (SDP) could include a single die disposed over a substrate, with a single layer of thermal barrier material disposed either between the die and the substrate, or over a side of the die opposing the substrate, depending upon the desirable and undesirable directions of heat conduction. In another embodiment, a substrate-free package could include multiple dies in a stack with one or more layers of thermal barrier material between adjacent dies. In still another embodiment, a substrate-free package with a single die (e.g., chip-scale packaging) could include a single die with one or more layers of thermal barrier material disposed thereon. In yet another embodiment, a discrete semiconductor died (e.g., not provided in a package) could be provided with one or more layers of thermal barrier material disposed thereon.

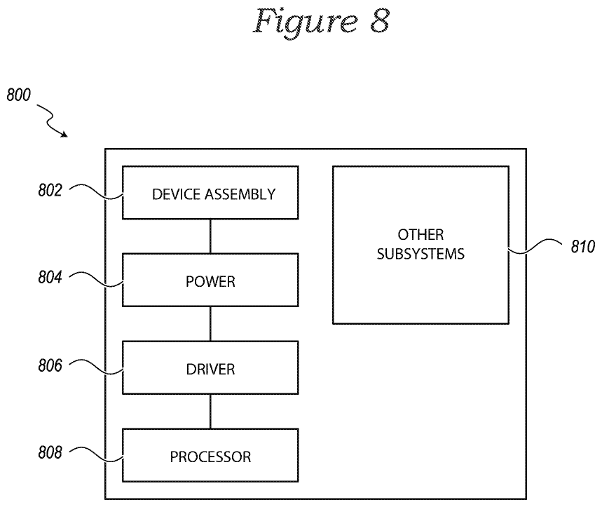

Any one of the semiconductor devices and semiconductor device assemblies described above with reference to FIGS. 2-7 can be incorporated into any of a myriad of larger and/or more complex systems, a representative example of which is system 600 shown schematically in FIG. 8. The system 800 can include a semiconductor device assembly (e.g., or a discrete semiconductor device) 802, a power source 804, a driver 806, a processor 808, and/or other subsystems or components 810. The semiconductor device assembly 802 can include features generally similar to those of the semiconductor devices described above with reference to FIGS. 2-5. The resulting system 800 can perform any of a wide variety of functions, such as memory storage, data processing, and/or other suitable functions. Accordingly, representative systems 800 can include, without limitation, hand-held devices (e.g., mobile phones, tablets, digital readers, and digital audio players), computers, vehicles, appliances and other products. Components of the system 800 may be housed in a single unit or distributed over multiple, interconnected units (e.g., through a communications network). The components of the system 800 can also include remote devices and any of a wide variety of computer readable media.

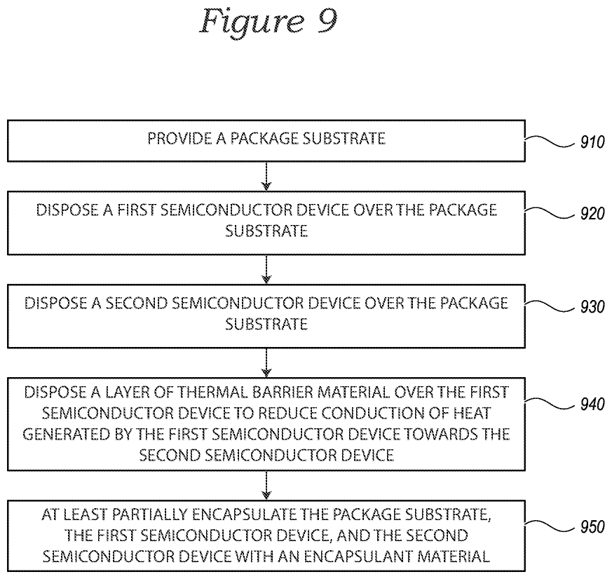

FIG. 9 is a flow chart illustrating a method of making a semiconductor device assembly. The method includes providing a package substrate (box 910), disposing a first semiconductor device over the package substrate, the first semiconductor device configured to generate heat during operation (box 920), and disposing a second semiconductor device over the package substrate (box 930). The layer further comprises disposing a layer of thermal barrier material over the first semiconductor device (box 940), wherein the layer of thermal barrier material configured to reduce conduction of the heat generated by the first semiconductor device towards the second semiconductor device. The method further comprises at least partially encapsulating the package substrate, the first semiconductor device, and the second semiconductor device with an encapsulant material (box 950).

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present technology. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present technology.

What is claimed is:

1. A semiconductor device assembly, comprising:
a package substrate;
a first semiconductor device disposed over the package substrate, the first semiconductor device configured to generate heat during operation;
a second semiconductor device disposed over the package substrate;
a layer of thermal barrier material disposed over the first semiconductor device; and
an encapsulant material at least partially encapsulating the package substrate, the first semiconductor device, and the second semiconductor device,
wherein the layer of thermal barrier material is configured to reduce conduction of the heat generated by the first semiconductor device towards the second semiconductor device.

2. The semiconductor device assembly of claim 1, wherein the layer of thermal barrier material is directly in contact with a back side of the first semiconductor device.

3. The semiconductor device assembly of claim 1, wherein the layer of thermal barrier material is directly in contact with a back side of the second semiconductor device.

4. The semiconductor device assembly of claim 1, wherein the layer of thermal barrier material comprises icon oxide glass, tetraethoxysilane (TEOS), polyimide, a ceramic film, a ceramic die, or a combination thereof.

5. The semiconductor device assembly of claim 1, wherein the layer of thermal barrier material has a thermal conductivity K of less than 5 W/(m ° K).

6. The semiconductor device assembly of claim 1, wherein the layer of thermal barrier material has a thickness of between 2 μm and 50 μm.

7. The semiconductor device assembly of claim 1, wherein the layer of thermal barrier material has a plan area substantially similar to the first semiconductor device, the second semiconductor device, or both.

8. The semiconductor device assembly of claim 1, wherein the layer of thermal barrier material has a plan area substantially less than the first semiconductor device.

9. The semiconductor device assembly of claim 1, further comprising one or more thermally conductive structures disposed in the substrate under the first semiconductor device and configured to conduct the heat from the first semiconductor device out of the semiconductor device assembly.

10. The semiconductor device assembly of claim 9, wherein the one or more thermally conductive structures are electrically isolated from any circuits of the first semiconductor device.

11. The semiconductor device assembly of claim 9, wherein the one or more thermally conductive structures comprise copper, aluminum, or an alloy thereof.

12. The semiconductor device assembly of claim 9, wherein the one or more thermally conductive structures comprise vias, heat pipes, metal plugs, or a combination thereof.

13. A method of making a semiconductor device assembly, comprising:
providing a package substrate;
disposing a first semiconductor device over the package substrate, the first semiconductor device configured to generate heat during operation;
disposing a second semiconductor device over the package substrate;
disposing a layer of thermal barrier material over the first semiconductor device, the layer of thermal barrier material configured to reduce conduction of the heat generated by the first semiconductor device towards the second semiconductor device; and
at least partially encapsulating the package substrate, the first semiconductor device, and the second semiconductor device with an encapsulant material.

14. The method of claim 13, wherein disposing the layer of thermal barrier material comprises depositing the layer of thermal barrier material over a back side of the first semiconductor device or over a back side of the second semiconductor device by sputtering, physical vapor deposition (PVD), chemical vapor deposition (CVD), atomic layer deposition (ALD), spin coating, or adhesive attachment.

15. The method of claim 13, wherein disposing the layer of thermal barrier material comprises adhering a film comprising the layer of thermal barrier material over a back side of the first semiconductor device or over a back side of the second semiconductor device.

16. The method of claim 13, wherein the layer of thermal barrier material comprises silicon oxide glass, tetraethoxysilane (TEOS), polyimide, a ceramic film, a ceramic die, or a combination thereof.

17. The method of claim 13, wherein the layer of thermal barrier material has a thermal conductivity κ of less than 5 W/(m ° K).

18. The method of claim 13, wherein the layer of thermal barrier material has a thickness of between 2 μm and 50 μm.

19. A semiconductor device assembly, comprising:
a package substrate;
a first semiconductor device disposed over the package substrate, the first semiconductor device configured to generate heat during operation;
a stack of second semiconductor devices disposed over the first semiconductor device;
a layer of thermal barrier material disposed between the first semiconductor device and the stack of second semiconductor devices; and
an encapsulant material at least partially encapsulating the package substrate, the first semiconductor device, and the second semiconductor device,
wherein the layer of thermal barrier material is configured to reduce conduction of the heat generated by the first semiconductor device towards the second semiconductor device.

20. The semiconductor device assembly of claim 19, further comprising one or more spacers disposed between the package substrate and the stack of second semiconductor devices.

21. The semiconductor device assembly of claim 19, further comprising one or more thermally conductive structures disposed in the substrate under the first semiconductor device and configured to conduct the heat from the first semiconductor device out of the semiconductor device assembly.
